(19) United States
(12) Patent Application Publication
(10) Pub. No.: US 2024/0321831 A1
(43) Pub. Date: Sep. 26, 2024

(54) SEMICONDUCTOR PACKAGE

(71) Applicant: Samsung Electronics Co., Ltd., Suwon-si (KR)

(72) Inventors: Insup SHIN, Suwon-si (KR); Hyeongmun KANG, Suwon-si (KR); Yuduk KIM, Suwon-si (KR); Seungwoo SIM, Suwon-si (KR)

(73) Assignee: Samsung Electronics Co., Ltd., Suwon-si (KR)

(21) Appl. No.: 18/606,534

(22) Filed: Mar. 15, 2024

(30) Foreign Application Priority Data
Mar. 24, 2023 (KR) 10-2023-0039002
Apr. 21, 2023 (KR) 10-2023-0052989

(51) Int. Cl. H01L 25/065; H01L 23/00; H10B 80/00

(52) U.S. Cl. CPC H01L 25/0657; H01L 24/05; H01L 24/06; H01L 24/16; H01L 24/32; H01L 24/73; H01L 2224/05012; H01L 2224/06131; H01L 2224/16148; H01L 2224/32148; H01L 2224/73204; H01L 2225/06513; H01L 2924/1436; H10B 80/00

(57) ABSTRACT

Provided is a semiconductor package including a first semiconductor chip, a plurality of second semiconductor chips sequentially stacked on the first semiconductor chip, a plurality of conductive front pads on lower surfaces of the plurality of second semiconductor chips, a plurality of conductive rear pads attached to an upper surface of the first semiconductor chip and an upper surface of each of the plurality of second semiconductor chips, and including a plurality of first bonding pads and a plurality of second bonding pads in different regions, and a plurality of chip connection terminals between the plurality of conductive front pads and the plurality of conductive rear pads, wherein each of the plurality of second bonding pads includes a supporting part configured to support each of the plurality of chip connection terminals, and a fixing part protruding from an upper surface of the supporting part.

### CROSS-REFERENCE TO RELATED APPLICATION

This application is based on and claims priority under 35 U.S.C. § 119 to Korean Patent Application Nos. 10-2023-0039002, filed on Mar. 24, 2023, and 10-2023-0052989, filed on Apr. 21, 2023, in the Korean Intellectual Property Office, the disclosures of each of which are incorporated by reference herein in their entirety.

### BACKGROUND

The inventive concepts relate to semiconductor packages, and more particularly, to semiconductor packages including a plurality of vertically stacked semiconductor chips.

In accordance with the rapid development of the electronics industry and the needs of users, a semiconductor package mounted on an electronic product is required to provide high performance and include various functions, and thus a semiconductor package including a plurality of semiconductor chips has been proposed.

In addition, to reduce the size of a semiconductor package including a plurality of semiconductor chips, a semiconductor package in which a plurality of semiconductor chips are vertically stacked is being developed.

### SUMMARY

The inventive concepts provide semiconductor packages including a plurality of vertically stacked semiconductor chips with improved reliability.

According to aspects of the inventive concepts, there is provided a semiconductor package. The semiconductor package includes a first semiconductor chip, a plurality of second semiconductor chips sequentially stacked on the first semiconductor chip, a plurality of conductive front pads on lower surfaces of the plurality of second semiconductor chips, a plurality of conductive rear pads attached to an upper surface of the first semiconductor chip and an upper surface of each of the plurality of second semiconductor chips, and including a plurality of first bonding pads and a plurality of second bonding pads in different regions, and a plurality of chip connection terminals between the plurality of conductive front pads and the plurality of conductive rear pads, wherein each of the plurality of second bonding pads includes a supporting part configured to support each of the plurality of chip connection terminals, and a fixing part protruding from an upper surface of the supporting part and extending in a first horizontal direction.

According to other aspects of the inventive concepts, there is provided a semiconductor package. The semiconductor package includes a first semiconductor chip, a plurality of second semiconductor chips sequentially stacked on the first semiconductor chip, a plurality of conductive front pads on lower surfaces of the plurality of second semiconductor chips, a plurality of conductive rear pads attached to an upper surface of the first semiconductor chip and an upper surface of each of the plurality of second semiconductor chips, from a planar perspective, and including a plurality of first bonding pads in central regions of the first semiconductor chip and the plurality of second semiconductor chips from a planar perspective and a plurality of second bonding pads in edge regions of the first semiconductor chip and the plurality of second semiconductor chips from a planar perspective, and a plurality of chip connection terminals between the plurality of conductive front pads and the plurality of conductive rear pads, and wherein each of the plurality of second bonding pads includes a supporting part configured to support each of the plurality of chip connection terminals, and a fixing part protruding from the upper surface of the supporting part on one side of the supporting part.

According to other aspects of the inventive concepts, there is provided a semiconductor package. The semiconductor package includes a buffer chip, a plurality of memory cell chips sequentially stacked on the buffer chip, a plurality of first conductive front pads on a lower surface of the buffer chip, a plurality of second conductive front pads on lower surfaces of the plurality of memory cell chips, a plurality of conductive rear pads attached to an upper surface of the buffer chip and an upper surface of each of the plurality of memory cell chips, and from a planar perspective, including a plurality of first bonding pads in a central region of the buffer chip and the plurality of memory cell chips, and a plurality of second bonding pads in an edge region around the central region, a plurality of package connection terminals respectively attached to the plurality of first conductive front pads, a plurality of chip connection terminals between the plurality of second conductive front pads and the plurality of conductive rear pads, a plurality of insulating adhesive layers between the buffer chip and each of the plurality of memory cell chips and surrounding a plurality of chip connection terminals, and a molding layer surrounding the buffer chip, the plurality of memory cell chips, and the plurality of insulating adhesive layers, and wherein each of the plurality of second bonding pads includes a supporting part configured to support each of the plurality of chip connection terminals, and a fixing part protruding from the upper surface of the supporting part on one side of the supporting part and extending in a first horizontal direction, wherein a first group of second bonding pads selected from among the plurality of second bonding pads are spaced apart from a second group of second bonding pads selected from among the plurality of second bonding pads based on a first imaginary line of symmetry passing through a center of the buffer chip and a center of the plurality of memory cell chips, and the first imaginary line of symmetry extending straight in the first horizontal direction, wherein the fixing parts of the first group of second bonding pads are to face each other with the fixing parts of the second group of second bonding pads.

### BRIEF DESCRIPTION OF THE DRAWINGS

Example embodiments will be more clearly understood from the following detailed description taken in conjunction with the accompanying drawings in which:

FIG. 1 is a cross-sectional view of a semiconductor package according to some example embodiments;

FIG. 2A is a plan layout showing a planar arrangement of some components of a semiconductor package according to some example embodiments;

FIG. 2B is an enlarged plan view illustrating a portion “EX1” in FIG. 2A;

FIG. 3A is a cross-sectional view illustrating a main configuration of a semiconductor package according to example embodiments, and is a cross-sectional view taken along line X1-X1′ of FIG. 2A;

FIG. 3B is a cross-sectional view illustrating a main configuration of a semiconductor package according to example embodiments, and is a cross-sectional view taken along line Y1-Y1′ of FIG. 2A;

FIG. 4 is a cross-sectional view illustrating a main configuration of a semiconductor package according to example embodiments, and is an enlarged cross-sectional view illustrating a portion marked “EX2” in FIG. 3A;

FIG. 5 is a plan view illustrating second bonding pads of a semiconductor package according to some example embodiments;

FIG. 6A is a plan layout showing a planar arrangement of some components of a semiconductor package according to some example embodiments;

FIG. 6B is a plan view illustrating a portion corresponding to FIG. 2B of a semiconductor package according to some example embodiments;

FIG. 7 is a cross-sectional view illustrating a second bonding pad of a semiconductor package according to some example embodiments;

FIG. 8 is a planar layout showing a planar arrangement of some components of a semiconductor package according to some example embodiments;

FIG. 9A is a cross-sectional view illustrating a main configuration of a semiconductor package according to some example embodiments, and is a cross-sectional view taken along line X2-X2′ of FIG. 8;

FIG. 9B is a cross-sectional view illustrating a main configuration of a semiconductor package according to some example embodiments, and is a cross-sectional view taken along line Y2-Y2′ of FIG. 8;

FIG. 10 is a plan layout showing a plan arrangement of some components of a semiconductor package according to some example embodiments;

FIG. 11A is a cross-sectional view illustrating a main configuration of a semiconductor package according to some example embodiments, and is a cross-sectional view taken along line X3-X3′ of FIG. 10;

FIG. 11B is a cross-sectional view illustrating a main configuration of a semiconductor package according to some example embodiments, and is a cross-sectional view taken along line Y3-Y3′ of FIG. 10; and

FIGS. 12A to 12H are cross-sectional views illustrating a method of manufacturing a semiconductor package according to some example embodiments, and are shown according to a process sequence.

### DETAILED DESCRIPTION

Hereinafter, some example embodiments will be described in detail with reference to the accompanying drawings. The same reference numerals are used for the same components in the drawings, and duplicate descriptions thereof are omitted.

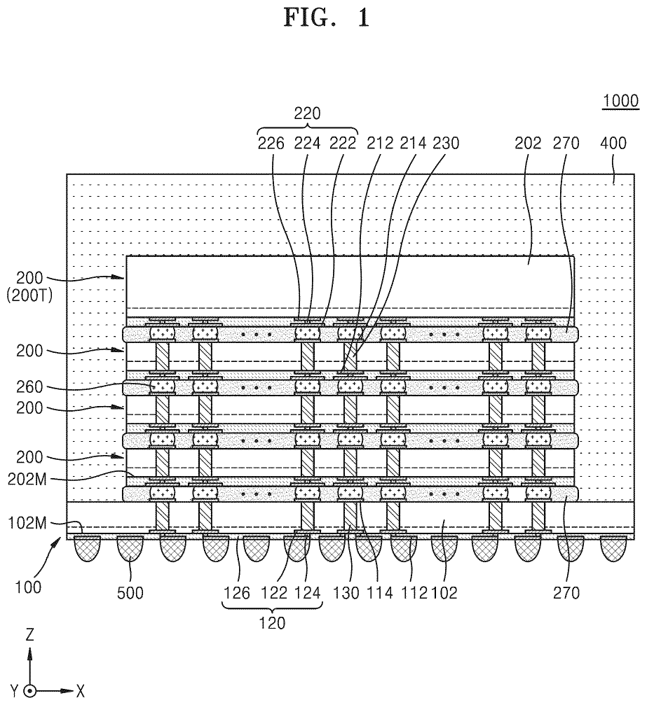

FIG. 1 is a cross-sectional view of a semiconductor package 1000 according to some example embodiments.

Referring to FIG. 1, the semiconductor package 1000 may include a first semiconductor chip 100 and a plurality of second semiconductor chips 200 sequentially stacked on the first semiconductor chip 100. According to some example embodiments, an insulating adhesive layer 270 may be disposed between different semiconductor chips that are vertically stacked. For example, each insulating adhesive layer 270 may be disposed between the first semiconductor chip 100 and the lowermost second semiconductor chip 200 among the plurality of second semiconductor chips 200, and between two adjacent second semiconductor chips 200 among the plurality of second semiconductor chips 200. For example, the semiconductor package 1000 may include a plurality of insulating adhesive layers 270, and the number of insulating adhesive layers 270 may be the same as the number of second semiconductor chips 200.

In FIG. 1, the semiconductor package 1000 is illustrated as including one first semiconductor chip 100 and four second semiconductor chips 200 but is not limited thereto. For example, the semiconductor package 1000 may include one, two, four, eight, or more semiconductor devices (e.g., semiconductor chips 200). In some other example embodiments, the semiconductor package 1000 may include a multiple of four second semiconductor chips 200. When the semiconductor package 1000 includes a plurality of second semiconductor chips 200, the plurality of second semiconductor chips 200 may be sequentially stacked on the first semiconductor chip 100 in the vertical direction (Z direction).

According to some example embodiments, the width and size of the first semiconductor chip 100 in the horizontal direction (X direction and/or Y direction) may be greater than the widths and sizes of the plurality of second semiconductor chips 200 in the horizontal direction (X direction and/or Y direction). Edges of the first semiconductor chip 100 may not be aligned with edges of the plurality of second semiconductor chips 200 in a vertical direction (Z direction). For example, from a planar perspective, the plurality of second semiconductor chips 200 may be disposed in a region defined by an edge of the first semiconductor chip 100. For example, the plurality of second semiconductor chips 200 may vertically overlap the first semiconductor chip 100.

According to some example embodiments, the first semiconductor chip 100 may include a first substrate 102 having a main surface 102M, a first wiring layer 120, and a plurality of first through electrodes 130. A plurality of first conductive front pads 112 may be attached to a lower surface of the first semiconductor chip 100, and a plurality of first conductive rear pads 114 may be attached to an upper surface of the first semiconductor chip 100. According to some example embodiments, the plurality of first conductive front pads 112 may be spaced apart from each other on the lower surface of the first semiconductor chip 100, and the plurality of first conductive rear pads 114 may be spaced apart from each other on the upper surface of the first semiconductor chip 100.

According to some example embodiments, the second semiconductor chip 200 may include a second substrate 202 having a main surface 202M, a second wiring layer 220, and a plurality of second through electrodes 230. A plurality of second conductive front pads 212 may be attached to a lower surface of the second semiconductor chip 200, and a plurality of second conductive rear pads 214 may be attached to an upper surface of the second semiconductor chip 200. According to some example embodiments, the plurality of second conductive front pads 212 may be disposed spaced apart from each other on the lower surfaces of the plurality of second semiconductor chips 200, and the plurality of second conductive rear pads 214 may be spaced apart from each other on the upper surface of the second semiconductor chip 200.

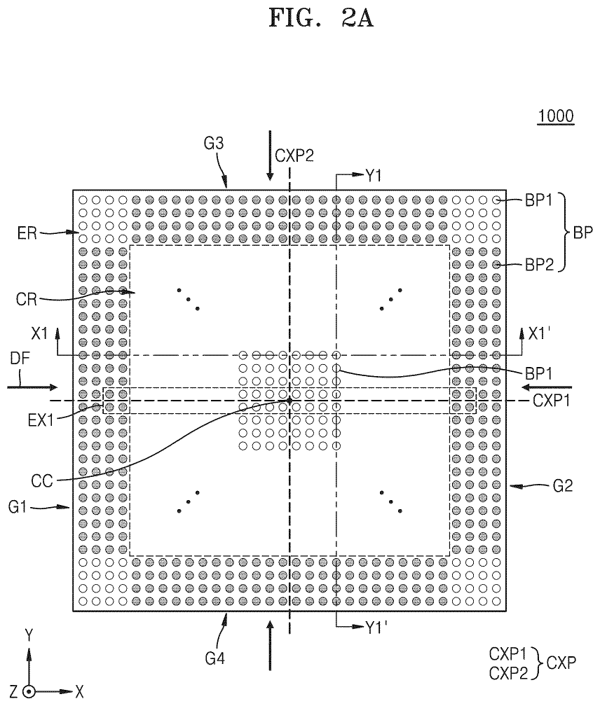

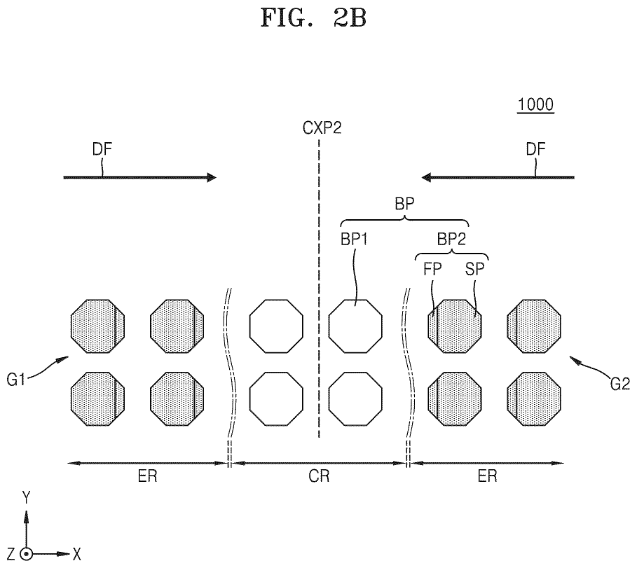

In this specification, the plurality of first conductive rear pads 114 and the plurality of second conductive rear pads 214 described with reference to FIG. 1 may respectively correspond to a plurality of rear pads BP described below (see FIGS. 2 to 4).

In some example embodiments, each of the first conductive front pad 112, the first conductive rear pad 114, the second conductive front pad 212, and the second conductive rear pad 214 may be formed by a plating process such as electrolytic plating or electroless plating. For example, each of the first conductive front pad 112, the first conductive rear pad 114, the second conductive front pad 212, and the second conductive rear pad 214 may include copper.

In some example embodiments, the first substrate 102 and the second substrate 202 may each include a semiconductor element such as silicon (Si) or germanium (Ge). In some example embodiments, each of the first substrate 102 and the second substrate 202 may include a compound semiconductor such as silicon carbide (SiC), gallium arsenide (GaAs), indium arsenide (InAs), and indium phosphide (InP). The first substrate 102 and the second substrate 202 may each have an active surface and an inactive surface opposite to the active surface. The active surface and the inactive surface of the first substrate 102 may be respectively referred to as a first active surface and a first inactive surface, and the active surface and the inactive surface of the second substrate 202 may be respectively referred to as a second active surface and a second inactive surface. The second active surface of the second substrate 202 may face the first inactive surface of the first substrate 102. In FIG. 1, the first active surface of the first substrate 102 and the second active surface of the second substrate 202 are shown with dotted lines.

According to some example embodiments, each of the first substrate 102 and the second substrate 202 may include a plurality of individual devices of various types disposed on the active surface. The plurality of individual devices may include various microelectronic devices, for example, metal-oxide-semiconductor field effect transistors (MOSFETs) such as complementary metal-oxide-semiconductor (CMOS) transistors, system large scale integration (LSI), image sensors such as CMOS imaging sensors (CISs), micro-electro-mechanical systems (MEMS), active devices, passive devices, and the like. Although not shown, a first semiconductor device (not shown) may be disposed on the first active surface of the first substrate 102, and a second semiconductor device (not shown) may be disposed on the second active surface of the second substrate 202.

In this specification, the front surface of a semiconductor chip refers to a surface located on the active surface side of a substrate and the rear surface of the semiconductor chip refers to a surface located on the inactive surface side of the substrate. In this specification, the upper surface of the semiconductor chip refers to a surface located on the upper side in the drawings and the lower surface of the semiconductor chip refers to a surface located on the lower side in the drawings.

According to some example embodiments, the first semiconductor chip 100 and the plurality of second semiconductor chips 200 may be sequentially stacked face down in which the first active surface and the second active surface face down. For example, the first active surface of the first substrate 102 included in the first semiconductor chip 100 faces a side opposite to the plurality of second semiconductor chips 200, and the first inactive surface may face the plurality of second semiconductor chips 200. The second active surface of the second substrate 202 included in each of the plurality of second semiconductor chips 200 faces the first semiconductor chip 100, and the second inactive surface may face a side opposite to the first semiconductor chip 100.

In some example embodiments, the first semiconductor chip 100 and the plurality of second semiconductor chips 200 may include dynamic random access memory (DRAM), static random access memory (SRAM), flash memory, electrically erasable and programmable read-only memory (EEPROM), phase-change random access memory (PRAM), PRAM), magnetic random access memory (MRAM), and/or resistive random access memory (RRAM).

In some example embodiments, the first semiconductor chip 100 may not include a memory cell. For example, a first semiconductor device included in the first semiconductor chip 100 may include a serial-parallel conversion circuit, design for test (DFT), joint test action group (JTAG), a test logic circuit such as memory built-in self-test (MBIST), and/or a signal interface circuit such as a physical interface transceiver (PHY). For example, the first semiconductor chip 100 may be a buffer chip for controlling the plurality of second semiconductor chips 200.

In some example embodiments, the first semiconductor chip 100 may be a buffer chip for controlling HBM DRAM, and the plurality of second semiconductor chips 200 may be memory cell chips having HBM DRAM cells controlled by the first semiconductor chip 100. The first semiconductor chip 100 may be called a buffer chip or a master chip, and the second semiconductor chip 200 may be called a memory cell chip or a slave chip. The first semiconductor chip 100 and the plurality of second semiconductor chips 200 stacked on the first semiconductor chip 100 may be collectively referred to as HBM DRAM devices or HBM DRAM chips.

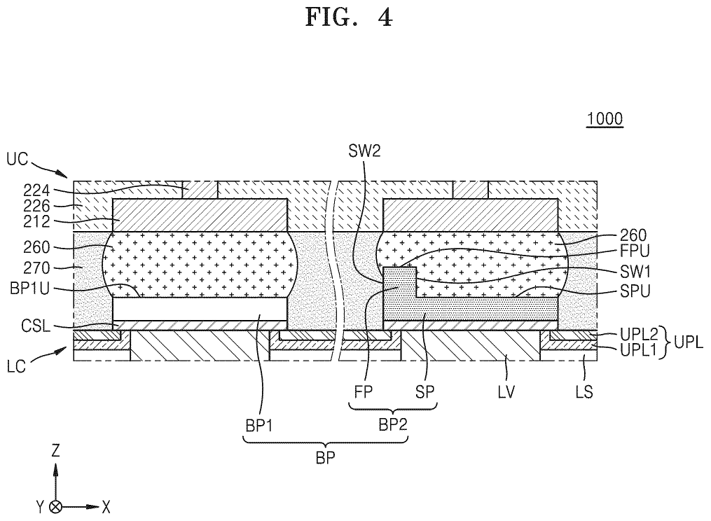

According to some example embodiments, a first wiring layer 120 may be disposed on the first active surface of the first substrate 102 and a protective layer UPL (see FIG. 4) may be disposed on the first inactive surface. A plurality of first conductive front pads 112 may be disposed on the lower surface of the first wiring layer 120, and a plurality of first conductive rear pads 114 may be disposed on an upper surface of a protective layer UPL (see FIG. 4). For example, a plurality of first conductive rear pads 114 may be disposed on an upper surface of the first semiconductor chip 100 and a plurality of first conductive front pads 112 may be disposed on a lower surface of the first semiconductor chip 100. A plurality of package connection terminals 500 may be respectively attached to the plurality of first conductive front pads 112. The plurality of package connection terminals 500 may function as external connection terminals of the semiconductor package 1000. The plurality of package connection terminals 500 may connect the semiconductor package 1000 to the outside. In some example embodiments, the plurality of package connection terminals 500 may be bumps or solder balls.

According to some example embodiments, the first wiring layer 120 may include a plurality of first wiring patterns 122, a plurality of first wiring vias 124, and a first inter-wiring insulating layer 126. The plurality of first wiring vias 124 may be connected to upper and/or lower surfaces of the plurality of first wiring patterns 122. In some example embodiments, the plurality of first wiring patterns 122 may be spaced apart from each other at different vertical levels, and the plurality of first wiring vias 124 may connect to each other first wiring patterns 122 disposed at different vertical levels. The plurality of first wiring patterns 122 and the plurality of first wiring vias 124 may be electrically connected to the plurality of first through electrodes 130. The first inter-wiring insulating layer 126 may cover the plurality of first wiring patterns 122 and the plurality of first wiring vias 124. In some example embodiments, the plurality of first conductive front pads 112 may be portions disposed on a lower surface of the first inter-wiring insulating layer 126 among the plurality of first wiring patterns 122.

According to some example embodiments, the plurality of first through electrodes 130 vertically penetrate at least a portion of the first substrate 102 to electrically connect the plurality of first conductive front pads 112 and the plurality of first conductive rear pads 114 to each other. The plurality of first through electrodes 130 may penetrate at least a portion of the first substrate 102 and a protective layer UPL (see FIG. 4). For example, the first conductive front pad 112 and the first conductive rear pad 114 corresponding to each other may be electrically connected through the first through electrode 130, the first wiring pattern 122, and the first wiring via 124.

According to some example embodiments, a second wiring layer 220 may be disposed on the second active surface of the second substrate 202 and a protective layer UPL (see FIG. 4) may be disposed on the second inactive surface of the second substrate 202. A plurality of second conductive front pads 212 may be disposed on the lower surface of the second wiring layer 220, and a plurality of second conductive rear pads 214 may be disposed on an upper surface of a protective layer UPL (see FIG. 4). For example, a plurality of second conductive rear pads 214 may be disposed on an upper surface of the second semiconductor chip 200 and a plurality of second conductive front pads 212 may be disposed on a lower surface of the second semiconductor chip 200.

According to some example embodiments, the second wiring layer 220 may include a plurality of second wiring patterns 222, a plurality of second wiring vias 224, and a second inter-wiring insulating layer 226. The plurality of second wiring vias 224 may be connected to upper and/or lower surfaces of the plurality of second wiring patterns 222. In some example embodiments, the plurality of second wiring patterns 222 may be arranged spaced apart from each other at different vertical levels, and the plurality of second wiring vias 224 may connect to each other second wiring patterns 222 disposed at different vertical levels. The plurality of second wiring patterns 222 and the plurality of second wiring vias 224 may be electrically connected to the plurality of second through electrodes 230. The second inter-wiring insulating layer 226 may cover the plurality of second wiring patterns 222 and the plurality of second wiring vias 224. In some example embodiments, the plurality of second conductive front pads 212 may be portions disposed on a lower surface of the second inter-wiring insulating layer 226 among the plurality of second wiring patterns 222.

According to some example embodiments, the plurality of second penetration electrodes (e.g., second through electrode) 230 vertically penetrate at least a portion of the second substrate 202 to electrically connect the plurality of second conductive front pads 212 and the plurality of second conductive rear pads 214 to each other. For example, the second conductive front pad 212 and the second conductive rear pad 214 corresponding to each other may be electrically connected through the second through electrode 230, the second wiring pattern 222, and the second wiring via 224.

In some example embodiments, each of the plurality of first wiring patterns 122, the plurality of first wiring vias 124, the plurality of second wiring patterns 222, and the plurality of second wiring vias 224 may include metals such as copper (Cu), aluminum (Al), tungsten (W), titanium (Ti), tantalum (Ta), molybdenum (Mo), cobalt (Co), nickel (Ni), alloys thereof, and/or nitrides thereof. In some example embodiments, each of the first inter-wiring insulating layer 126 and the second inter-wiring insulating layer 226 may include a High Density Plasma (HDP) oxide film, an ethyl silicate (TEOS) oxide film, Tonen SilaZene (TOSZ), Spin On Glass (SOG), Undoped Silica Glass (USG), or a low-k dielectric layer.

In some example embodiments, each of the plurality of first through electrodes 130 and the plurality of second through electrodes 230 may include a conductive plug and a conductive barrier film surrounding the conductive plug. The conductive plug may include Cu or W. For example, the conductive plug may be made of Cu, CuSn, CuMg, CuNi, CuZn, CuPd, CuAu, CuRc, CuW, W, and/or a W alloy but is not limited thereto. For example, the conductive plug may include at least one of Al, Au, Bc, Bi, Co, Cu, Hf, In, Mn, Mo, Ni, Pb, Pd, Pt, Rh, Rc, Ru, Ta, Te, Ti, W, Zn, and/or Zr, and may include one or more laminated structures. The conductive barrier film may include at least one material selected from W, WN, WC, Ti, TiN, Ta, TaN, Ru, Co, Mn, WN, Ni, and/or NiB, and may consist of a single layer or layers.

According to some example embodiments, a plurality of chip connection terminals 260 may be respectively attached to lower surfaces of the plurality of second conductive front pads 212. As illustrated in FIG. 1, a plurality of chip connection terminals 260 may be disposed between the first conductive rear pad 114 and the second conductive front pad 212 facing each other, or between the second conductive rear pad 214 and the second conductive front pad 212 facing each other. Specifically, the plurality of chip connection terminals 260 may be disposed between the plurality of first conductive rear pads 114 and the plurality of second conductive front pads 212 attached to the lowermost second semiconductor chip 200 among the plurality of second semiconductor chips 200, and between the plurality of second conductive front pads 212 attached to the remaining second semiconductor chips 200 among the plurality of second semiconductor chips 200 and the plurality of second conductive rear pads 214 attached to other second semiconductor chips 200 below the pads, so that the first semiconductor chip 100 and the plurality of second semiconductor chips 200 may be electrically connected to each other. In some example embodiments, the plurality of chip connection terminals 260 may be conductive pillars, bumps, solder balls, and the like.

In this specification, the second conductive front pad 212 to which the chip connection terminal 260 is attached may be referred to as a front connection pad, and the first conductive rear pad 114 and the second conductive rear pad 214 to which the chip connection terminal 260 is attached may be referred to as rear connection pads. The first conductive front pad 112 may be referred to as an external connection pad.

In some example embodiments, among the plurality of second semiconductor chips 200, the second semiconductor chip 200 disposed at the uppermost position farthest from the first semiconductor chip 100 may not include an inner lower surface connection pad 2 and the second through electrode 230. In some example embodiments, among the plurality of second semiconductor chips 200, the uppermost second semiconductor chip 200T disposed farthest from the first semiconductor chip 100 may have a thickness greater than that of the remaining second semiconductor chips 200.

According to some example embodiments, the plurality of insulating adhesive layers 270 may be disposed between each of the first semiconductor chip 100 and the plurality of second semiconductor chips 200, and the first semiconductor chip 100 and the plurality of second semiconductor chips 200 may have a plurality of insulating adhesive layers 270 therebetween and may be spaced apart in the vertical direction (Z direction). Each of the plurality of insulating adhesive layers 270 may fill a gap between the first semiconductor chip 100 and the plurality of second semiconductor chips 200 while surrounding the plurality of chip connection terminals 260. In some example embodiments, sidewalls of the plurality of first and second conductive rear pads 114 and 214 may be covered by the insulating adhesive layer 270.

In some example embodiments, each of the plurality of insulating adhesive layers 270 may include a non-conductive film (NCF), a non-conductive paste (NCP), an insulating polymer, and/or an epoxy resin.

According to some example embodiments, the semiconductor package 1000 may further include a molding layer 400 surrounding the plurality of second semiconductor chips 200 and the plurality of insulating adhesive layers 270 on the first semiconductor chip 100. The molding layer 400 may be formed of, for example, Epoxy Mold Compound (EMC). In some example embodiments, the molding layer 400 may cover the side surfaces of the plurality of second semiconductor chips 200, the side surfaces of the plurality of insulating adhesive layers 270, and the upper surface of the uppermost second semiconductor chip 200T among the plurality of second semiconductor chips 200. In some other example embodiments, the molding layer 400 may cover the side surfaces of the plurality of second semiconductor chips 200 and the side surfaces of the insulating adhesive layer 270 but may not cover the upper surface of the uppermost second semiconductor chip 200T among the plurality of second semiconductor chips 200. For example, the upper surface of the molding layer 400 and the upper surface of the uppermost second semiconductor chip 200T may form the same plane.

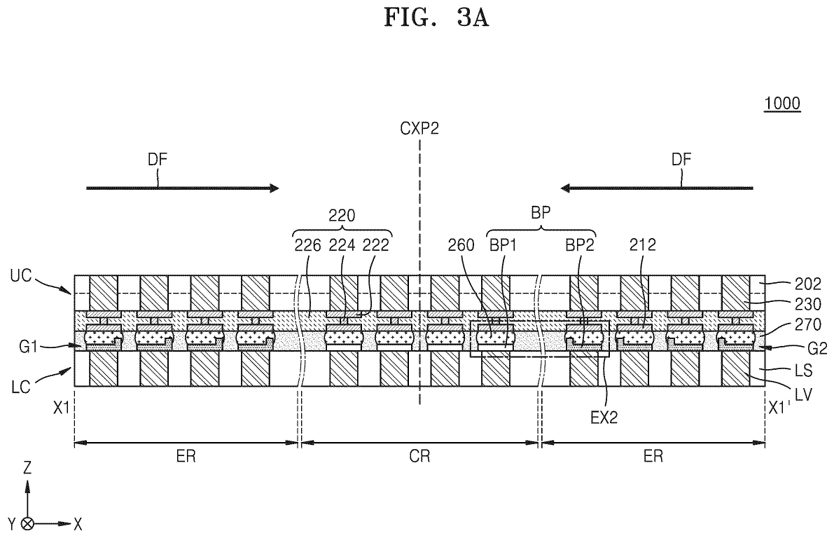

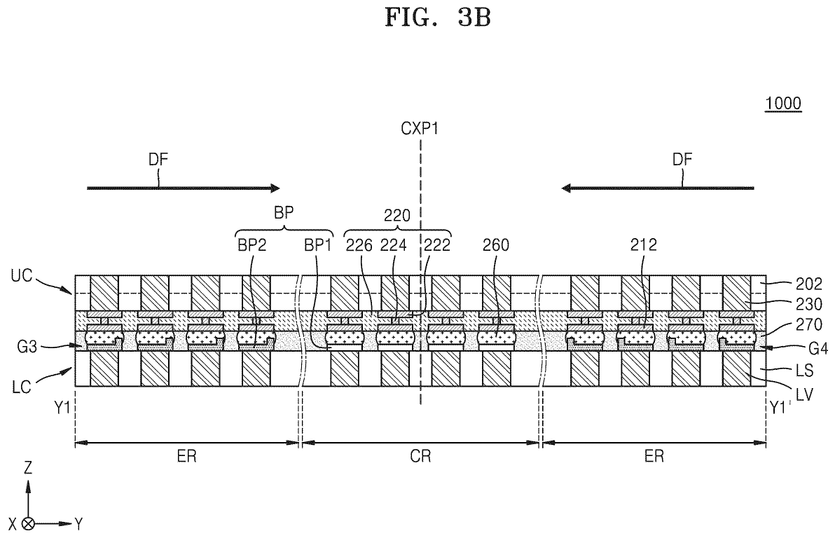

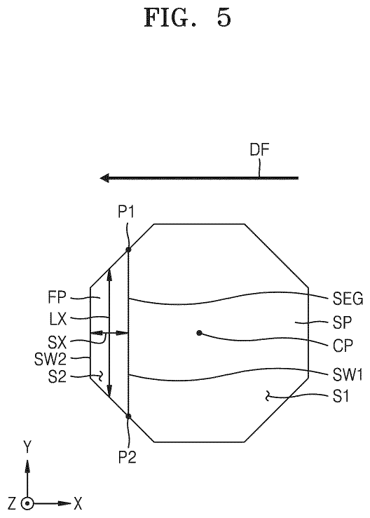

FIG. 2A is a plan layout showing a planar arrangement of some components of a semiconductor package 1000 according to some example embodiments, and FIG. 2B is an enlarged view illustrating a portion “EX1” in FIG. 2A. FIG. 3A is a cross-sectional view illustrating a main configuration of a semiconductor package 1000 according to some example embodiments, and is a cross-sectional view taken along line X1-X1′ of FIG. 2A. FIG. 3B is a cross-sectional view illustrating a main configuration of the semiconductor package 1000 according to some example embodiments, and is a cross-sectional view taken along line Y1-Y1′ of FIG. 2A. Specifically, FIGS. 3A and 3B are cross-sectional views illustrating a bonding region between sequentially stacked lower semiconductor chips LC and upper semiconductor chips UC. For example, FIGS. 3A and 3B represent bonding regions between the first semiconductor chip 100 of the semiconductor package 1000 described with reference to FIG. 1 and the second semiconductor chip 200 on the first semiconductor chip 100, or represent a bonding region between two second semiconductor chips 200 sequentially stacked. FIG. 4 is a cross-sectional view illustrating a main configuration of a semiconductor package according to some example embodiments, and is an enlarged cross-sectional view illustrating a portion marked “EX2” in FIG. 3A. FIG. 5 is a plan view illustrating a second bonding pad BP2 of a semiconductor package according to some example embodiments.

In FIGS. 3A, 3B, and 4, the lower semiconductor chip LC may be the first semiconductor chip 100 and the upper semiconductor chip UP may be the second semiconductor chip 200. In this case, the lower substrate LS of the lower semiconductor chip LC is the first substrate 102 described with reference to FIG. 1, and the plurality of lower through electrodes LV may be the plurality of first through electrodes 130 described with reference to FIG. 1. The plurality of conductive rear pads BP may be the plurality of first conductive rear pads 114 described with reference to FIG. 1.

Alternatively, both the lower semiconductor chip LC and the upper semiconductor chip UP may be the second semiconductor chip 200. In this case, the lower substrate LS of the lower semiconductor chip LC is the first substrate 202 described with reference to FIG. 1, and the plurality of lower through electrodes LV may be the plurality of first through electrodes 130 described with reference to FIG. 1. The plurality of conductive rear pads BP may be the plurality of first conductive rear pads 114 described with reference to FIG. 1.

In some example embodiments, the semiconductor package 1000 may include a plurality of protective layers UPL covering the upper surface of the first substrate 102 and the upper surface of the plurality of second substrates 200 described with reference to FIG. 1. Referring to FIG. 4, each of the plurality of protective layers UPL may include a lower protective layer UPL1 and an upper protective layer UPL2. For example, the lower protective layer UPL1 of each of the plurality of protective layers UPL may cover the upper surface of the lower substrate LS and sidewalls of portions of the plurality of lower through electrodes LV protruding from the upper surface of the lower substrate LS. The upper protective layer UPL2 may cover the lower protective layer UPL1.

In some example embodiments, the top of the lower protective layer UPL1, the upper surface of the upper protective layer UPL2, and the upper surfaces of the plurality of lower through electrodes LV may be on the same vertical level to form a coplanar surface. In some example embodiments, a conductive seed layer CSL may be disposed to cover upper surfaces of the plurality of lower penetration electrodes LV, an uppermost portion of the lower protective layer UPL1, and a portion of the upper surface of the upper protective layer UPL2. For example, the lower surface of the conductive seed layer CSL may be in contact with upper surfaces of the plurality of lower through electrodes LV and an upper surface of the conductive seed layer CSL may be in contact with a plurality of conductive rear pads BP. In some example embodiments, the conductive seed layer CSL may include titanium, titanium nitride, and/or titanium tungsten but is not limited thereto.

According to some example embodiments, a plurality of conductive rear pads BP contacting an upper surface of the conductive seed layer CSL may be disposed on the conductive seed layer CSL. For example, the conductive seed layer CSL may be disposed between the plurality of lower through electrodes LV and the plurality of conductive rear pads BP.

According to some example embodiments, the plurality of conductive rear pads BP may include a plurality of first bonding pads BP1 and a plurality of second bonding pads BP2. For example, the plurality of first bonding pads BP1 and the plurality of second bonding pads BP2 may be in contact with the plurality of chip connection terminals 260, respectively, and may mediate an electrical connection between an individual semiconductor chip including a plurality of first bonding pads BP1 and a plurality of second bonding pads BP2 and another semiconductor chip disposed on the individual semiconductor chip.

According to some example embodiments, upper surfaces BP1U of the plurality of first bonding pads BP1 may have a flat surface. For example, the upper surface BP1U of the plurality of first bonding pads BP1 may have a substantially uniform vertical level, and upper surfaces BP1U of the plurality of first bonding pads BP1 may contact the plurality of chip connection terminals 260, respectively. In this specification, “vertical level” refers to a height in the vertical direction (Z direction or −Z direction) from the main surface 102M of the first substrate 102.

According to some example embodiments, each of the plurality of second bonding pads BP2 may include a supporting part SP and a fixing part FP disposed on the supporting part SP and protruding from the upper surface SPU of the supporting part SP. For example, the upper surface FPU of the fixing part FP may be at a higher vertical level than the upper surface SPU of the supporting part SP. The supporting part SP of the plurality of second bonding pads BP2 is a main part in contact with the plurality of chip connection terminals 260, and may have a wider planar area than the fixing part FP. In some example embodiments, a portion of the upper surface SPU of the supporting part SP not covered by the fixing part FP may have a larger area than the upper surface FPU of the fixing part FP. The fixing parts FP of the plurality of second bonding pads BP2 may serve as a threshold or a wall that limits the movement of the plurality of chip connection terminals 260 in the horizontal direction (X direction and/or Y direction) when bonding the plurality of semiconductor chips 100 and 200. For example, when the plurality of semiconductor chips 100 and 200 are bonded by a thermal compression method, the fixing parts FP of the plurality of second bonding pads BP2 may prevent or reduce in likelihood the plurality of semiconductor chips 100 and 200 from slipping or rotating due to pressure applied in the vertical direction (Z direction) to prevent or reduce in likelihood misalignment.

In some example embodiments, the upper surface BP1U of the plurality of first bonding pads BP1 may be at a lower vertical level than the upper surface FPU of the fixing part FP of the plurality of second bonding pads BP2. In some example embodiments, the upper surface BP1U of the plurality of first bonding pads BP1 may be at the same vertical level as the upper surface SPU of the supporting part SP of the plurality of second bonding pads BP2.

According to some example embodiments, the fixing part FP may extend in a straight direction on one side of the supporting part SP. For example, the fixing part FP may extend in the second horizontal direction (Y direction) as illustrated in FIGS. 2B, 4, and 5 but is not limited thereto. For example, the fixing part FP may extend in the first horizontal direction (X direction) or in a diagonal direction with respect to the first horizontal direction (X direction) and the second horizontal direction (Y direction).

Referring to FIG. 5, from a planar perspective, a first point P1 and a second point P2 selected from the perimeters of each of the plurality of second bonding pads BP2, and a first line segment SEG connecting the first point P1 to the second point P2 may be defined. According to some example embodiments, the first line segment SEG may extend in a second horizontal direction (Y direction) and may be spaced apart from the center CP of each of the plurality of second bonding pads BP2. According to some example embodiments, from a planar perspective, each of the plurality of second bonding pads BP2 may include a first region partitioned by a first line segment SEG and a second region S2 having a smaller plane than the first region S1. For example, from a planar perspective, the first region may be a region not covered by the fixing part FP of the upper surface SPU of the supporting part SP, and the second region may be a region in which an upper surface FPU of the fixing part FP is disposed.

In some example embodiments, the fixing part FP may be disposed at an edge of the plurality of second bonding pads BP2 from a planar perspective. For example, from a planar perspective, the centers CP of the plurality of second bonding pads BP2 may be disposed within the supporting part SP, and the fixing part FP may be spaced apart from the center CP and extend in a straight line from the edge. In some example embodiments, the fixing part FP may have a first sidewall SW1 facing the center CP of the plurality of second bonding pads BP2 and a second sidewall SW2 opposite to the first sidewall SW1. In some example embodiments, the second sidewall SW2 of the fixing part FP may form part of the outer wall of each of the plurality of second bonding pads BP2.

In some example embodiments, the first sidewall SW1 and the first sidewall SW1 of the fixing part FP may be perpendicular to the upper surface SPU of the supporting part SP. In some example embodiments, the plurality of second bonding pads BP2 may have an L-shaped cross-section. For example, each of the plurality of second bonding pads BP2 may have an L-shape in a vertical section in the first horizontal direction (X direction) passing through the center CP.

In some example embodiments, the fixing part FP may have a major axis LX in the extension direction and a minor axis SX orthogonal to the major axis LX. It is shown In FIG. 5 that the fixing part FP extends in the second horizontal direction (Y direction), and has a major axis LX in the second horizontal direction (Y direction) and a minor axis SX in the first horizontal direction (X direction), but the inventive concepts are not limited thereto. For example, the fixing part FP may extend in the first horizontal direction (X direction), and in this case, may have a major axis LX in the first horizontal direction (X direction) and a minor axis SX in the second horizontal direction (Y direction).

In FIGS. 2B and 5, it is shown that a plurality of conductive rear pads BP each have an octagonal planar shape, and the first sidewall SW1 and the second sidewall SW2 of the fixing part FP are disposed on two planes parallel to each other, but the inventive concepts are not limited thereto. For example, each of the plurality of conductive rear pads BP may have a circular planar shape, and the second sidewall SW2 of the fixing part FP may have a curved surface. In addition, each of the plurality of conductive rear pads BP may have a rectangular shape, a hexagonal shape, or the like.

In some example embodiments, for each of the plurality of second bonding pads BP2, a fixing array direction DF, which is a direction from the center CP of each of the plurality of second bonding pads BP2 toward the fixing part FP, may be defined. In some example embodiments, a selected part of the plurality of second bonding pads BP2 and another selected part of the plurality of second bonding pads BP2 may have different fixing array directions DF.

In some example embodiments, the plurality of first bonding pads BP1 may have a shape similar to that of the supporting parts SP of the plurality of second bonding pads BP2. For example, the upper surface BP1U of the plurality of first bonding pads BP1 may have the same vertical level as the upper surface SPU of the supporting part SP of the plurality of second bonding pads BP2. For example, the plurality of first bonding pads BP1 may have the same planar area as the supporting parts SP of the plurality of second bonding pads BP2. In some example embodiments, the plurality of first bonding pads BP1 and the supporting parts SP of the plurality of second bonding pads BP2 may be formed together in the same manufacturing process. In some other example embodiments, the plurality of first bonding pads BP1 may have a planar shape that is different from that of the plurality of second bonding pads BP2 or may have a planar area that is different from that of the plurality of second bonding pads BP2.

In some example embodiments, the supporting part SP and the fixing part FP of the plurality of second bonding pads BP2 may overlap the plurality of conductive front pads 212 in the vertical direction (Z direction). In some example embodiments, the plurality of chip connection terminals 260 may overlap the supporting part SP and the fixing part FP of the plurality of second bonding pads BP2 in the vertical direction (Z direction). In some example embodiments, each of a plurality of chip connection terminals 260 may cover the parts not covered by the fixing part FP of the upper surface SPU of the supporting part SP, a first sidewall SW1 of the fixing part FP, and an upper surface FPU of the fixing part FP.

Referring to FIG. 2A, from a planar perspective, the first semiconductor chip 100 and the plurality of second semiconductor chips 200 may each include a center region CR and an edge region ER. The first semiconductor chip 100 may have a larger planar area than the plurality of second semiconductor chips 200, and, from a planar perspective, the plurality of first conductive rear pads 114 described with reference to FIG. 1 may be disposed within a boundary of a portion of the upper surface of the first semiconductor chip 100 vertically overlapping the second semiconductor chip 200. In this case, the center region CR and the edge region ER of the first semiconductor chip 100 may be disposed within a boundary of a portion vertically overlapping the second semiconductor chip 200.

In some example embodiments, the plurality of second bonding pads BP2 may be disposed in the edge region ER. Accordingly, when the lower semiconductor chip LC and the upper semiconductor chip UC are bonded, the plurality of second bonding pads BP2 may easily prevent or reduce in likelihood the plurality of chip connection terminals 260 from moving in the region where the angular momentum is large based on the chip center CC, which is the center of each of the semiconductor chips LC and UC, and misalignment of the upper semiconductor chip UC by rotating about the chip center CC may be prevented or reduced in likelihood. In some example embodiments, the plurality of first bonding pads BP1 may be mainly disposed in the center region CR and may be disposed in a region of the edge region ER where the plurality of second bonding pads BP2 are not disposed. In some other example embodiments, some of the plurality of second bonding pads BP2 may be disposed in the central region CR.

In FIG. 2A, a plurality of conductive rear pads BP are spaced apart from each other at a constant distance and densely filled in the center region CR and the edge region ER, but the inventive concepts are not limited thereto. For example, a plurality of conductive rear pads BP may be spaced apart from each other at different distances.

According to some example embodiments, a first group of second bonding pads BP2 selected from among the plurality of second bonding pads BP2 may be disposed symmetrically with a second group of second bonding pads BP2 selected from among the plurality of second bonding pads BP2 and spaced apart from the first group of second bonding pads BP2 based on the symmetry line. In some example embodiments, some of the plurality of first bonding pads BP1 may be disposed between the first group of second bonding pads BP2 and the second group of second bonding pads BP2. In some other example embodiments, the plurality of first bonding pads BP1 may not be disposed between the first group of second bonding pads BP2 and the second group of second bonding pads BP2.

In some example embodiments, the fixing parts FP of the first group of second bonding pads BP2 may be disposed to face the fixing parts FP of the second group of second bonding pads BP2. For example, the fixing array direction DF of the first group and the fixing array direction DF of the second group may face each other.

In some other example embodiments, the fixing parts FP of the first group of second bonding pads BP2 may be disposed opposite to the fixing parts FP of the second group of second bonding pads BP2. For example, the fixing array direction DF of the first group and the fixing array direction DF of the second group may be opposite to each other.

Referring to FIG. 2A, from a planar perspective, a central region CR may have four sides, and an edge region ER of a plurality of second bonding pads BP2 may be disposed around the four sides. According to some example embodiments, the plurality of second bonding pads BP2 may include first to fourth groups G1, G2, G3, and G4 of the second bonding pads BP2 disposed around each of the four sides. According to some example embodiments, the first and second groups G1 and G2 of second bonding pads BP2 may be disposed on both sides of the center region CR in the first horizontal direction (X direction). For example, the first group G1 of second bonding pads BP2 may be spaced apart from the second group G2 of second bonding pads BP2 in the first horizontal direction (X direction) with the plurality of first bonding pads BP1 disposed in the central region CR disposed therebetween. According to some example embodiments, the third and fourth groups G3 and G4 of second bonding pads BP2 may be disposed on both sides of the center region CR in the second horizontal direction (Y direction). For example, the third group G3 of second bonding pads BP2 may be spaced apart from the fourth group G4 of second bonding pads BP2 in the second horizontal direction (Y direction) with the plurality of first bonding pads BP1 disposed in the central region CR disposed therebetween. According to some example embodiments, the plurality of second bonding pads BP2 may be symmetrically disposed with respect to a symmetry line CXP passing through the chip center CC.

Referring to FIGS. 2A, 2B, 3A, and 3B, a first symmetry line CXP1 extending in a first horizontal direction (X direction) and passing through the chip center CC and a second symmetry line CXP2 extending in a second horizontal direction (Y direction) and passing through the chip center CC may be defined. According to some example embodiments, the first group G1 of second bonding pads BP2 and the second group of second G2 bonding pads BP2 may be symmetrically disposed with respect to the second symmetry line CXP2, and the third group G3 of second bonding pads BP2 and the fourth group G4 of second bonding pads BP2 may be symmetrically disposed with respect to the first symmetry line CXP1.

In some example embodiments, the fixing parts FP of the first group G1 of second bonding pads BP2 and the fixing parts FP of the second group G2 of second bonding pads BP2 may face each other. For example, the fixing array direction DF of the first group G1 of second bonding pad BP2 and the fixing array direction DF of the second group G2 of second bonding pad BP2 may face each other. In some example embodiments, the fixing parts FP of the third group G3 of second bonding pads BP2 and the fixing parts FP of the fourth group G4 of second bonding pads BP2 may face each other. For example, the fixing array direction DF of the third group G3 of second bonding pad BP2 and the fixing array direction DF of the fourth group G4 of second bonding pad BP2 may face each other.

According to some example embodiments, the plurality of second bonding pads BP2 may include a plurality of sets of fixing parts FP disposed to face each other. According to some example embodiments, the first and second groups G1 and G2 of second bonding pads BP2 whose fixing parts FP are facing each other may constitute the first set of second bonding pads BP2, and the third and fourth groups G3 and G4 of second bonding pads BP2 whose the fixing parts FP are facing each other may constitute a second set of second bonding pads BP2. For example, the first set of second bonding pads BP2 may face each other in a first horizontal direction (X direction), and the second set of second bonding pads BP2 may face each other in a second horizontal direction (Y direction). In some example embodiments, directions in which the plurality of sets of second bonding pads BP2 facing each other may be different from each other. In some other example embodiments, directions in which the plurality of sets face each other may be the same. In some other example embodiments, the plurality of sets may include some sets facing each other in the same direction and some sets facing each other in different directions.

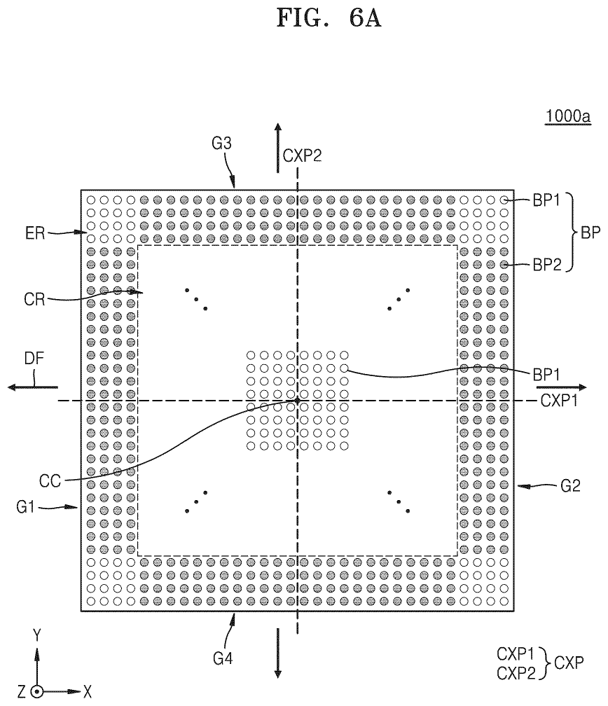

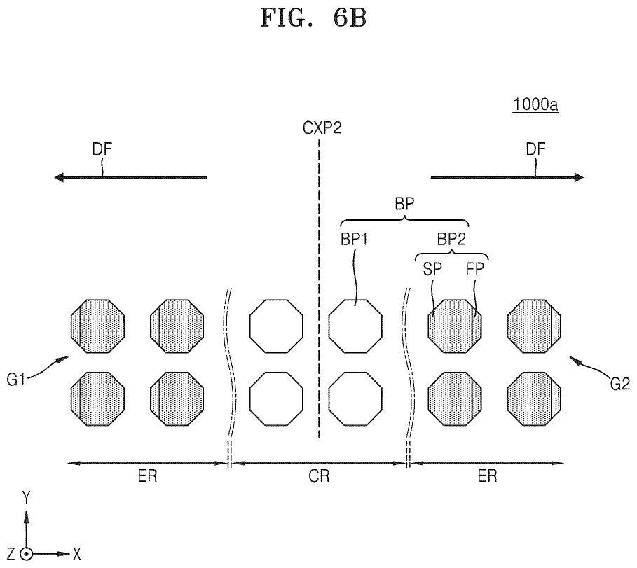

FIGS. 6A and 6B are plan views illustrating a planar arrangement of some components of a semiconductor package 1000a according to other example embodiments. Specifically, FIG. 6A shows a portion corresponding to FIG. 2A, and FIG. 6B shows a portion corresponding to FIG. 2B. In some example embodiments, the fixing parts FP of the first group G1 of second bonding pads BP2 and the fixing parts FP of the second group G2 of second bonding pads BP2 may be opposite to each other. For example, the fixing array direction DF of the first group G1 of second bonding pad BP2 and the fixing array direction DF of the second group G2 of second bonding pad BP2 may be opposite to each other. In some example embodiments, the fixing parts FP of the third group G3 of second bonding pads BP2 and the fixing parts FP of the fourth group G4 of second bonding pads BP2 may be disposed opposite to each other. For example, the fixing array direction DF of the third group G3 of second bonding pad BP2 of and the fixing array direction DF of the fourth group G4 of second bonding pad BP2 may be opposite to each other.

The semiconductor packages 1000 and 1000a may include a plurality of second bonding pads BP2 disposed so that fixing parts FP are opposite to each other or face each other, and the plurality of chip connection terminals 260 may be interlocked with the fixing parts FP of the plurality of second bonding pads BP2. For example, the plurality of second bonding pads BP2 disposed so that the fixing parts FP face each other or be opposite to each other, and the plurality of chip connection terminals 260 respectively disposed on the plurality of second bonding pads BP2 may have an engagement structure similar to a train rail and a derailment prevention wheel of a train placed on the rail. Accordingly, the horizontal direction (X direction and/or Y direction) movement of the lower semiconductor chip LC and the upper semiconductor chip UC is restricted, so that misalignment or distortion of alignment between the stacked chips LC and UC may be prevented or reduced in likelihood.

In FIGS. 2A and 6A, it is shown that the line of symmetry CXP extends in the first horizontal direction (X direction) or the second horizontal direction (Y direction), but the inventive concepts are not limited thereto. For example, the symmetry line CXP may extend in a diagonal direction with respect to the first horizontal direction (X direction) and the second horizontal direction (Y direction).

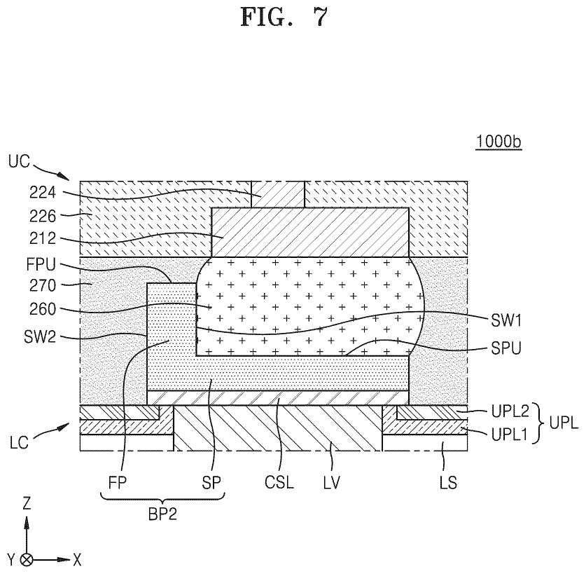

FIG. 7 is a cross-sectional view illustrating a plurality of second bonding pads BP2 of the semiconductor package 1000b according to some example embodiments.

Referring to FIG. 7, the supporting parts SP of the plurality of second bonding pads BP2 overlap with the plurality of conductive front pads 212 in the vertical direction (Z direction), and the fixing parts FP of the plurality of second bonding pads BP2 may not overlap the plurality of conductive front pads 212 in the vertical direction (Z direction). The fixing part FP of the semiconductor package 1000b according to FIG. 7 may have a height in the vertical direction (Z direction) higher than that of the fixing part FP of the semiconductor package 1000 described with reference to FIGS. 1 to 5. For example, the vertical level difference between the upper surface FPU of the fixing part FP and the upper surface SPU of the supporting part SP may be greater in the semiconductor package 1000b than in the semiconductor package 1000 described with reference to FIGS. 1 to 5. In some example embodiments, a portion of the upper surface SPU of the supporting part SP that is not covered by the fixing part FP may have a larger planar area than the lower surfaces of the plurality of conductive front pads 212.

In some example embodiments, the plurality of chip connection terminals 260 cover a part of the upper surface SPU of the supporting part SP and the first sidewall SW1 of the fixing part FP, but do not cover the upper surface FPU of the fixing part FP. For example, the part not covered by the fixing part FP of the upper surface SPU of the supporting part SP is in contact with each of the plurality of chip connection terminals 260, and the upper surface FPU of the fixing part FP may not come into contact with each of the plurality of chip connection terminals 260. In some other example embodiments, each of the plurality of chip connection terminals 260 may cover a part of the upper surface SPU of the supporting part SP, the first sidewall SW1 of the fixing part FP, and the upper surface FPU of the fixing part FP together.

In some example embodiments, the upper surface FPU of the fixing part FP of the plurality of second bonding pads BP2 may be covered by the insulating adhesive layer 270 and may be spaced apart from the second inter-wiring insulating layer 226 in the vertical direction (Z direction) with the insulating adhesive layer 270 disposed therebetween. In some other example embodiments, the upper surface FPU of the fixing part FP of the plurality of second bonding pads BP2 may contact the second inter-wiring insulating layer 226.

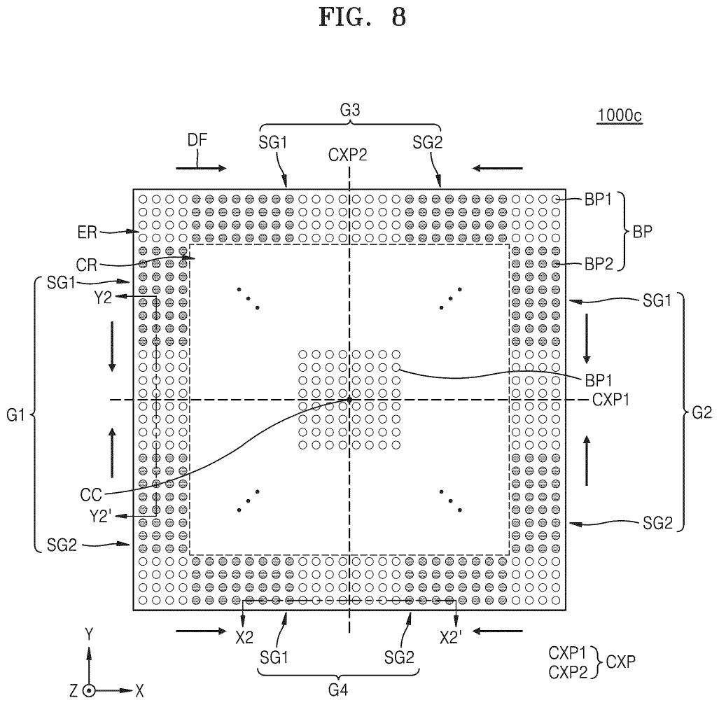

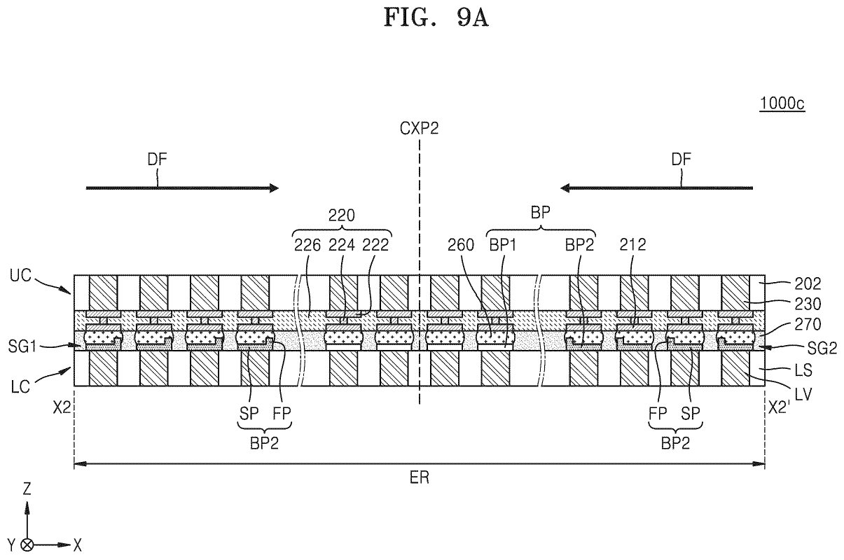

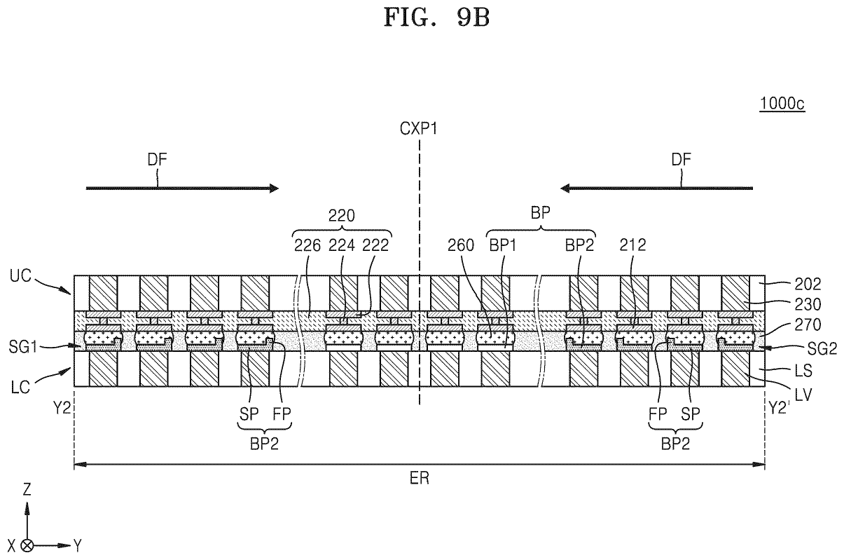

FIG. 8 is a planar layout showing a planar arrangement of some components of a semiconductor package 1000c according to some example embodiments. FIG. 9A is a cross-sectional view illustrating a main configuration of a semiconductor package according to some example embodiments, and is a cross-sectional view taken along line X2-X2′ of FIG. 8. FIG. 9B is a cross-sectional view illustrating a main configuration of a semiconductor package according to some example embodiments, and is a cross-sectional view taken along line Y2-Y2′ of FIG. 8. Specifically, FIGS. 9A and 9B are cross-sectional views illustrating a bonding region between sequentially stacked lower semiconductor chips LC and upper semiconductor chips UC. For example, FIGS. 9A and 9B represent a bonding region between a first semiconductor chip 100 and a second semiconductor chip 200 on the first semiconductor chip 100, or represent a bonding region between two second semiconductor chips 200 sequentially stacked. In FIGS. 8, 9A and 9B, the same reference numerals as those in FIGS. 1 to 5 denote the same members, and redundant description thereof will be omitted below. However, a new explanation will be provided for content that differs in structural arrangement relationships, and the like., even for the same member.

Referring to FIGS. 8, 9A and 9B, each of the first to fourth groups G1, G2, G3, and G4 of second bonding pads BP2 respectively disposed around the four sides of the central region CR may include two sub-groups SG1 and SG2. In some example embodiments, the first sub-group SG1 of second bonding pads BP2 and the second sub-group SG2 of second bonding pads BP2 may be spaced apart from each other based on a symmetry line CXP therebetween, and may be arranged symmetrically. In this specification, the first to fourth groups G1, G2, G3, and G4 of second bonding pads BP2 may be respectively referred to as first to fourth groups G1, G2, G3, and G4 for convenience, and the first and second sub-groups SG1 and SG2 of second bonding pads BP2 may be referred to as first and second sub-groups SG1 and SG2, respectively.

For example, the first sub-group SG1 and the second sub-group SG2 included in each of the first group G1 and the second group G2 may be spaced apart from each other in the second horizontal direction (Y direction) and may be arranged symmetrically based on the first line of symmetry CXP1. For example, the first sub-group SG1 and the second sub-group SG2 included in each of the third group G3 and the fourth group G4 may be spaced apart from each other in the first horizontal direction (X direction) and may be symmetrically disposed based on the second symmetry line CXP2.

In some example embodiments, the fixing part FP of the first sub-group SG1 and the fixing part FP of the second sub-group SG2 may face each other. For example, the fixing array direction DF of the first sub-group SG1 and the fixing array direction DF of the second sub-group SG2 may face each other. In some other example embodiments, the fixing part FP of the first sub-group SG1 and the fixing part FP of the second sub-group SG2 may be disposed opposite to each other. For example, the fixing array direction DF of the first sub-group SG1 and the fixing array direction DF of the second sub-group SG2 may be opposite to each other.

In some example embodiments, the first group G1 and the second group G2 may be symmetrically disposed with respect to the second symmetry line CXP2, and the third group G3 and the fourth group G4 may be symmetrically disposed with respect to the first symmetry line CXP1. In some example embodiments, the fixing array direction DF of the first sub-group SG1 included in the first group G1 and the fixing array direction DF of the first sub-group SG1 included in the second group G2 may be parallel to each other, and the fixing array direction DF of the second sub-group SG2 included in the first group G1 and the fixing array direction DF of the second sub-group SG2 included in the second group G2 may be parallel to each other. In some example embodiments, the fixing array direction DF of the first sub-group SG1 included in the third group G3 and the fixing array direction DF of the first sub-group SG1 included in the fourth group G4 may be parallel to each other, and the fixing array direction DF of the second sub-group SG2 included in the third group G3 and the fixing array direction DF of the second sub-group SG2 included in the fourth group G4 may be parallel to each other.

In some example embodiments, in the edge region ER, the first sub-group SG1 and the second sub-group SG2 may be spaced apart from each other with some of the plurality of first bonding pads BP1 disposed therebetween. For example, the first sub-group SG1 and the second sub-group SG2 included in the first and second groups G1 and G2 may be spaced apart from each other in the second horizontal direction (Y direction) with some of the plurality of first bonding pads BP1 disposed therebetween. For example, the first sub-group SG1 and the second sub-group SG2 included in the third and fourth groups G3 and G4 may be spaced apart from each other in the first horizontal direction (X direction) with some of the plurality of first bonding pads BP1 disposed therebetween.

In some other example embodiments, a plurality of first bonding pads BP1 may not be disposed between the first sub-group SG1 and the second sub-group SG2.

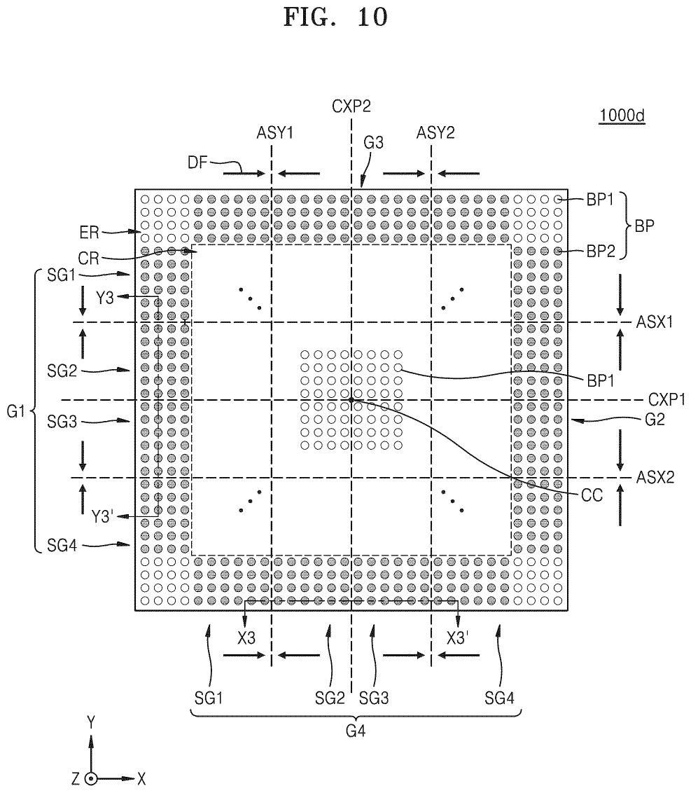

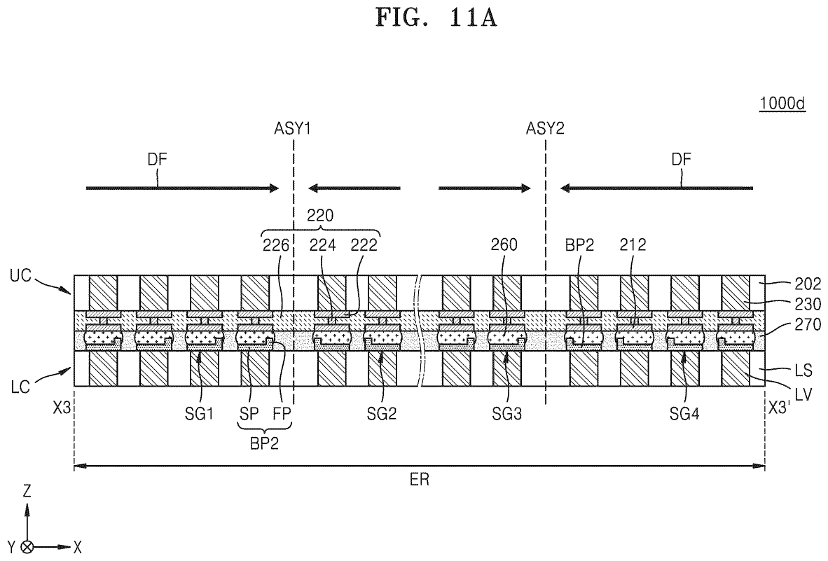

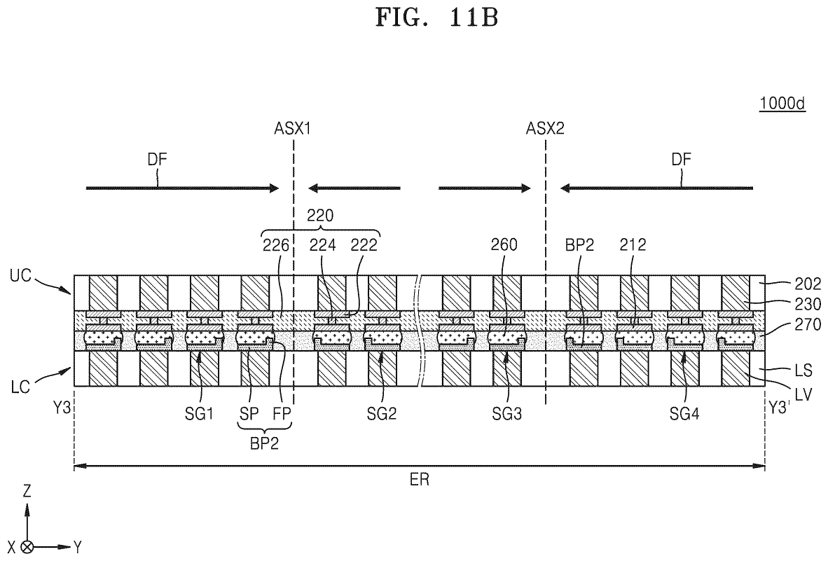

FIG. 10 is a planar layout showing a planar arrangement of some components of a semiconductor package according to some example embodiments. FIG. 11A is a cross-sectional view illustrating a main configuration of a semiconductor package according to some example embodiments, and is a cross-sectional view taken along line X3-X3′ of FIG. 10. FIG. 11B is a cross-sectional view illustrating a main configuration of a semiconductor package according to some example embodiments, and is a cross-sectional view taken along line Y3-Y3′ of FIG. 10. Specifically, FIGS. 11A and 11B are cross-sectional views illustrating a bonding region between sequentially stacked lower semiconductor chips and upper semiconductor chips. For example, FIGS. 11A and 11B represent a bonding region between a first semiconductor chip 100 and a second semiconductor chip 200 on the first semiconductor chip 100, or represent a bonding region between two second semiconductor chips 200 sequentially stacked. In FIGS. 10, 11A and 11B, the same reference numerals as those in FIGS. 1 to 5 denote the same members, and redundant description thereof will be omitted below. However, a new explanation will be provided for content that differs in structural arrangement relationships, and the like, even for the same member.

Referring to FIGS. 10, 9A and 9B, each of the first to fourth groups G1, G2, G3, and G4 of second bonding pads BP2 respectively disposed around the four sides of the central region CR may include four sub-groups SG1, SG2, SG3, and SG4. In some example embodiments, the first and second sub-groups SG1 and SG2 of second bonding pads BP2 and the third and fourth sub-groups SG3 and SG4 of second bonding pads BP2 may be spaced apart from each other with respect to the symmetry line CXP and may be symmetrically disposed. In this specification, the first to fourth sub-groups SG1, SG2, SG3, and SG4 of second bonding pads BP2 of may be referred to as first to second sub-groups SG1, SG2, SG3, and SG4, respectively.

For example, the first and second sub-groups SG1 and SG2 and the third and fourth sub-groups SG3 and SG4 included in each of the first group G1 and the second group G2 may be spaced apart from each other in the second horizontal direction (Y direction) based on the first symmetry line CXP1 and may be symmetrically disposed. For example, the first and second sub-groups SG1 and SG2 and the third and fourth sub-groups SG3 and SG4 included in the third group G3 and the fourth group G4 may be spaced apart from each other in the first horizontal direction (X direction) with respect to the second symmetry line CXP2 and may be symmetrically disposed.

In some example embodiments, the plurality of second bonding pads BP2 may be symmetrically arranged with respect to first to fourth sub-symmetrical lines ASX1, ASX2, ASY1, and ASY2 spaced apart from the chip center CC. The first and second sub-symmetric lines ASX1 and ASX2 are spaced apart from the chip center CC in a second horizontal direction (Y direction), and may extend parallel to each other along the first horizontal direction (X direction). For example, the first sub-symmetrical line ASX1 and the second sub-symmetrical line ASX2 may be symmetrically disposed based on the first symmetrical line CXP1 passing through the chip center CC. The third and fourth sub-symmetric lines ASY1 and ASY2 are spaced apart from the chip center CC in a first horizontal direction (X direction), and may extend parallel to each other along a second horizontal direction (Y direction). For example, the third sub-symmetrical line ASY1 and the fourth sub-symmetrical line ASY2 may be symmetrically disposed based on the second symmetrical line CXP2 passing through the chip center CC.

In some example embodiments, the fixing part FP of the first sub-group SG1 and the fixing part FP of the second sub-group SG2 included in the first and second groups G1 and G2 may be arranged to face each other based on the first sub-symmetrical line ASX1. For example, the fixing array direction DF of the first sub-group SG1 and the fixing array direction DF of the second sub-group SG2 included in the first and second groups G1 and G2, respectively, may face each other. In some example embodiments, the fixing part FP of the third sub-group SG3 and the fixing part FP of the fourth sub-group SG4 included in the first and second groups G1 and G2, respectively, may be arranged to face each other based on the second sub-symmetric line ASX2. For example, the fixing array direction DF of the third sub-group SG3 and the fixing array direction DF of the fourth sub-group SG4 included in the first and second groups G1 and G2, respectively, may face each other.

In some example embodiments, the fixing part FP of the first sub-group SG1 and the fixing part FP of the second sub-group SG2 included in the third and fourth groups G3 and G4, respectively, may be arranged to face each other based on the third sub-symmetric line ASY1. For example, the fixing array direction DF of the first sub-group SG1 and the fixing array direction DF of the second sub-group SG2 included in the third and fourth groups G3 and G4, respectively, may face each other. In some example embodiments, the fixing part FP of the third sub-group SG3 and the fixing part FP of the fourth sub-group SG4 included in the third and fourth groups G3 and G4, respectively, may be arranged to face each other based on the fourth sub-symmetrical line ASY2. For example, the fixing array direction DF of the third sub-group SG3 and the fixing array direction DF of the fourth sub-group SG4 included in the third and fourth groups G3 and G4, respectively, may face each other.

In some other example embodiments, the fixing array direction DF of the first sub-group SG1 and the fixing array direction DF of the second sub-group SG2 of each of the first to fourth groups G1, G2, G3, and G4 may be opposed to each other, and the fixing array direction DF of the third sub-group SG3 and the fixing array direction DF of the fourth sub-group SG4 of each of the first to fourth groups G1, G2, G3, and G4 may be opposed to each other.

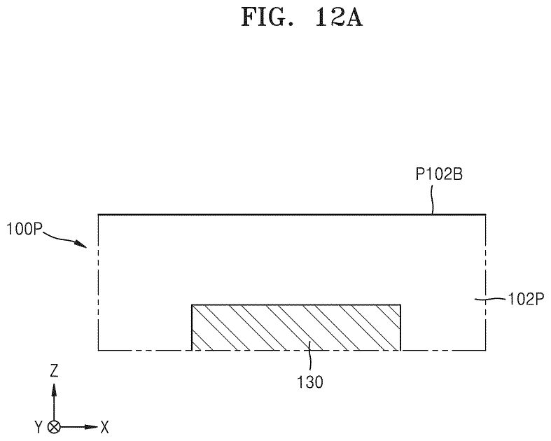

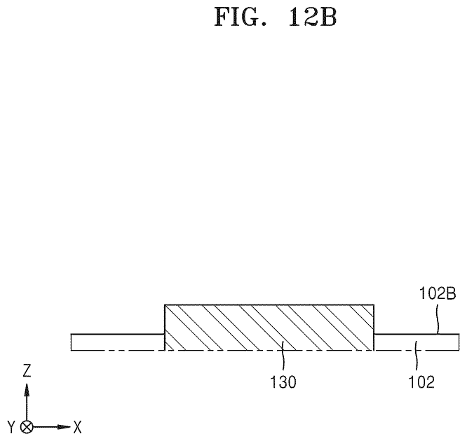

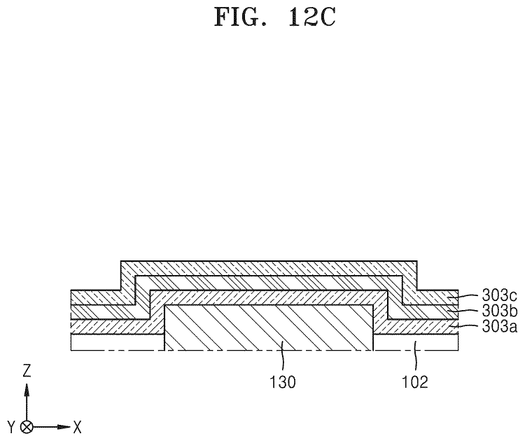

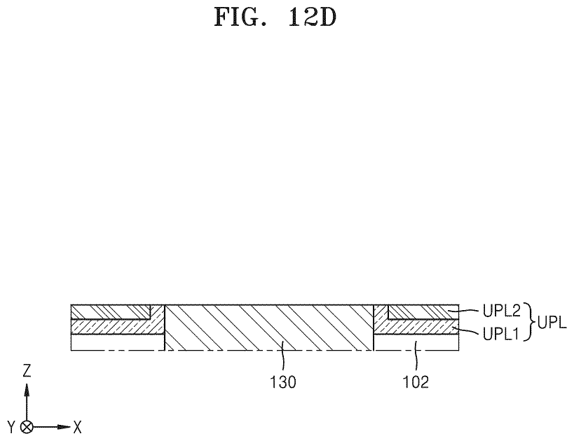

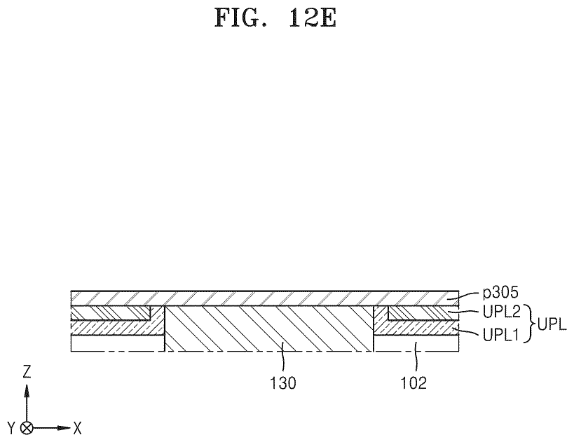

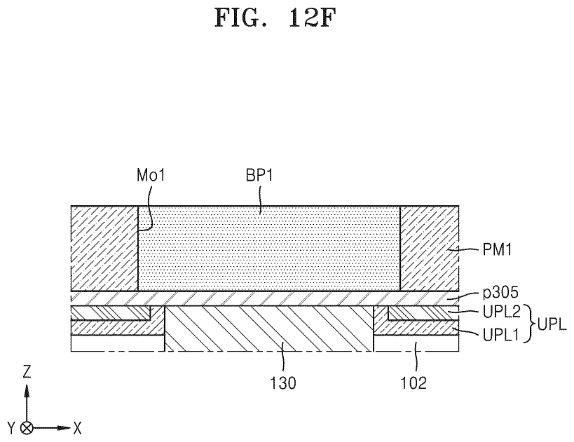

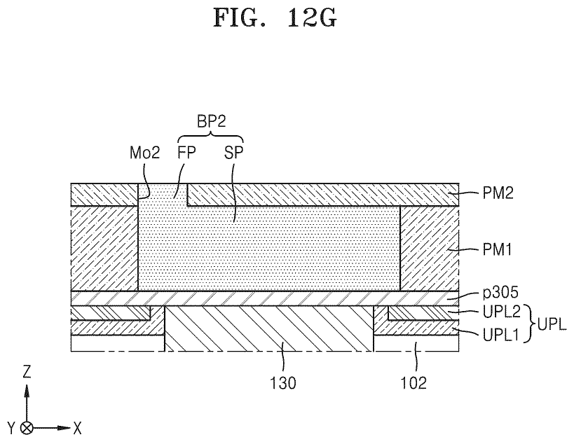

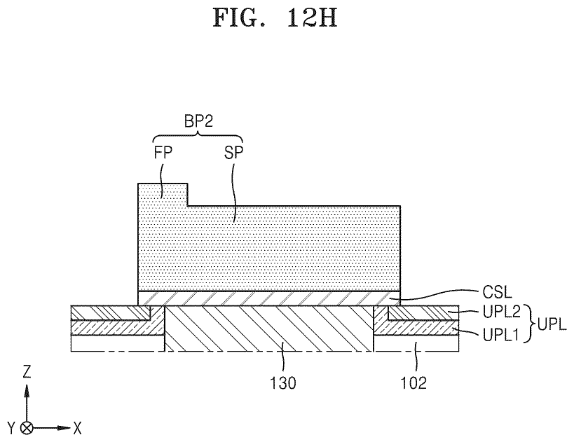

FIGS. 12A to 12H are cross-sectional views illustrating a manufacturing method of the semiconductor package 1000 according to some example embodiments according to a process sequence. Specifically, FIGS. 12A to 12H are cross-sectional views showing an upper portion (e.g., near a plurality of rear pads) of the first semiconductor chip 100 or the second semiconductor chip 200 in the bonding region of the semiconductor package 1000. In FIGS. 12A to 12H, the same reference numerals as those in FIGS. 1 to 5 denote the same members, and redundant descriptions thereof may be omitted below.

Referring to FIG. 12A, a preliminary semiconductor chip 100P may be prepared. The preliminary semiconductor chip 100P includes a preliminary substrate 102P, a first wiring layer 120 (see FIG. 1), and a plurality of first through electrodes 130 (see FIGS. 1, 3A, 3B, and 4). The first wiring layer 120 may include a plurality of first wiring patterns 122, a plurality of first wiring vias 124, and a first inter-wiring insulating layer 126 (see FIG. 1), and a plurality of first conductive front pads 112 (see FIG. 1) may be attached to a lower surface of the preliminary semiconductor chip 100P.

The preliminary substrate 102P may have an active surface (not shown) and a preliminary inactive surface P102B opposite to the active surface (not shown). For example, semiconductor devices may be disposed on an active surface (not shown) of the preliminary substrate 102P.

The plurality of first penetration electrodes (e.g., first through electrodes) 130 may be electrically connected to the plurality of first conductive front pads 112 (see FIG. 1) by penetrating at least a portion of the preliminary substrate 102P in the vertical direction (Z direction). For example, the first conductive front pad 112 and the first through electrode 130 corresponding to each other may be electrically connected through the first wiring pattern 122 and the first wiring via 124. The plurality of first through electrodes 130 extend in a vertical direction within the preliminary substrate 102P, but may not extend to the preliminary inactive surface P102B. That is, the upper portion including the upper surface of each of the plurality of first through electrodes 130 may be buried in the preliminary substrate 102P and not exposed to the outside.

Referring to FIGS. 12A and 12B together, a first substrate 102 having a first inactive surface 102B may be formed by removing a portion of the preliminary substrate 102P from the preliminary inactive surface P102B.

As a result of forming the first substrate 102 by removing a portion of the preliminary substrate 102P, upper portions of the plurality of first through electrodes 130 may protrude onto the first inactive surface 102B of the first substrate 102. A portion of each of the plurality of first through electrodes 130 may be buried in the first substrate 102, and another portion may protrude from the first inactive surface 102B to the outside of the first substrate 102.

Referring to FIGS. 12B and 12C together, a first preliminary protective layer 303a, a second preliminary protective layer 303b, and a third preliminary protective layer 303c are sequentially formed on the first inactive surface 102B of the first substrate 102, so that a preliminary protective layer having a stacked structure of the first preliminary protective layer 303a, the second preliminary protective layer 303b, and the third preliminary protective layer 303c is formed. Each of the first preliminary protective layer 303a, the second preliminary protective layer 303b, and the third preliminary protective layer 303c may be formed to conformally cover the first inactive surface 102B of the first substrate 102 and upper portions of each of the plurality of first through electrodes 130 sequentially. For example, the first preliminary protective layer 303a may conformally cover the first inactive surface 102B of the first substrate 102, and the upper surface of each of the plurality of first through electrodes 130 and a side surface of an upper part protruding onto the first inactive surface 102B of the first substrate 102, the second preliminary protective layer 303b may conformally cover the upper surface of the first preliminary protective layer 303a, and the third preliminary protective layer 303c may conformally cover the upper surface of the second preliminary protective layer 303b.

Referring to FIGS. 12C and 12D together, as a portion of the preliminary protective layer having a stacked structure of a first preliminary protective layer 303a, a second preliminary protective layer 303b, and a third preliminary protective layer 303c is removed, a protective layer UPL having a stacked structure of a lower protective layer UPL1 and an upper protective layer UPL2 may be formed. In this process, the plurality of first through electrodes 130 may be exposed. For example, a protective layer UPL may be formed by removing preliminary protective layers disposed at a vertical level higher than the upper surfaces of the plurality of first through electrodes 130.

Referring to FIGS. 12D and 12E together, a preliminary conductive seed layer p305 may be formed on the protective layer UPL and the plurality of first through electrodes 130. For example, the preliminary conductive seed layer p305 may conformally cover the upper surface of the protective layer UPL and the upper surface of the plurality of first through electrodes 130. For example, the preliminary conductive seed layer p305 may be formed by physical vapor deposition, but is not limited thereto.

Referring to FIGS. 12E and 12F together, a first mask layer PM1 having a plurality of first mask openings Mo1 may be formed on the preliminary conductive seed layer p305. For example, the first mask layer PM1 may include photoresist. In some example embodiments, the plurality of first mask openings Mo1 may be formed at positions corresponding to the plurality of first through electrodes 130. In some example embodiments, the horizontal width of the plurality of first mask openings Mo1 may have a greater value than the horizontal width of the plurality of first through electrodes 130. For example, a portion of an upper surface of the plurality of first through electrodes 130 and a top surface of a protective layer UPL adjacent to the plurality of first through electrodes 130 may be exposed on the bottom of the plurality of first mask openings Mo1.

Then, supporting parts SP of the plurality of first bonding pads BP1 (see FIGS. 1, 3A, 3B, and 4) and the plurality of second bonding pads BP2 may be formed by filling the conductive material within the plurality of first mask openings Mo1. For example, the supporting parts SP of the plurality of first bonding pads BP1 and the plurality of second bonding pads BP2 may be formed by a plating process such as electroplating or electroless plating.

Referring to FIGS. 12F and 12G together, a second mask layer PM2 having a plurality of second mask openings Mo2 may be formed on the supporting part SP of the first mask layer PM1, the plurality of first bonding pads BP1, and the plurality of second bonding pads BP2. For example, the second mask layer PM2 may include photoresist. In some example embodiments, the plurality of second mask openings Mo2 may be formed at a position corresponding to one of edges of the supporting part SP of the plurality of second bonding pads BP2. For example, the second mask layer PM2 may cover a portion of the upper surface of the plurality of first bonding pads BP1 and the upper surface of the supporting part SP of the plurality of second bonding pads BP2. In some example embodiments, portions of upper surfaces of the supporting parts SP of the plurality of second bonding pads BP2 may be exposed on the bottom surfaces of the plurality of second mask openings Mo2.

After that, a conductive material may be filled in the plurality of second mask openings MO2 to form the fixing parts FP of the plurality of second bonding pads BP2. For example, the fixing parts FP of the plurality of second bonding pads BP2 may be formed by a plating process such as electroplating or electroless plating.

Referring to FIGS. 12G and 12H together, parts of the first mask layer PM1, the second mask layer PM2, and the preliminary conductive seed layer p305 are removed from the result of FIG. 12G, so that a plurality of first conductive rear pads 114 and a conductive seed layer CSL may be formed, and an upper surface of the protective layer UPL may be exposed.

The protective layer UPL and the plurality of second conductive rear pads 214 of the second semiconductor chip 200 may be formed by referring to the manufacturing method of the protective layer UPL and the plurality of first conductive rear pads 114 of the first semiconductor chip 100 described with reference to FIGS. 12A to 12H.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a first semiconductor chip;
a plurality of second semiconductor chips sequentially stacked on the first semiconductor chip;
a plurality of conductive front pads on lower surfaces of the plurality of second semiconductor chips;
a plurality of conductive rear pads attached to an upper surface of the first semiconductor chip and an upper surface of each of the plurality of second semiconductor chips, and including a plurality of first bonding pads and a plurality of second bonding pads in different regions; and
a plurality of chip connection terminals between the plurality of conductive front pads and the plurality of conductive rear pads,
wherein each of the plurality of second bonding pads includes,
a supporting part configured to support each of the plurality of chip connection terminals; and
a fixing part protruding from an upper surface of the supporting part and extending in a first horizontal direction.

2. The semiconductor package of claim 1, wherein the fixing part is on an edge of each of the plurality of second bonding pads.

3. The semiconductor package of claim 1, wherein, from a planar perspective, centers of the plurality of second bonding pads are within the supporting part,
wherein the fixing part comprises a first sidewall facing the center of each of the plurality of second bonding pads and a second sidewall opposite to the first sidewall, and
wherein the first sidewall forms a right angle with an upper surface of the supporting part.

4. The semiconductor package of claim 1, wherein a portion of an upper surface of the supporting part not covered by the fixing part has a larger planar area than an upper surface of the fixing part.

5. The semiconductor package of claim 1, wherein the plurality of second bonding pads have an L-shaped cross-section.

6. The semiconductor package of claim 1, wherein the first semiconductor chip and each of the plurality of second semiconductor chips comprise a center region and an edge region around the center region, and
wherein the plurality of second bonding pads are on the edge region.

7. The semiconductor package of claim 1, wherein a first group of second bonding pads selected from among the plurality of second bonding pads is spaced apart from a second group of second bonding pads selected from among the plurality of second bonding pads based on a first imaginary line of symmetry passing through a center of the first semiconductor chip and a center of the plurality of second semiconductor chips and the first imaginary line of symmetry extending straight in the first horizontal direction, and
wherein the fixing parts of the first group of second bonding pads are to face each other with the fixing parts of the second group of second bonding pads.

8. The semiconductor package of claim 1, wherein a first group of second bonding pads selected from among the plurality of second bonding pads is spaced apart from a second group of second bonding pads selected from among the plurality of second bonding pads based on a first imaginary line of symmetry passing through a center of the first semiconductor chip and a center of the plurality of second semiconductor chips and the first imaginary line of symmetry extending straight in the first horizontal direction, and
wherein the fixing parts of the first group of second bonding pads are opposite to the fixing parts of the second group of second bonding pads.

9. The semiconductor package of claim 1, wherein a first group of second bonding pads selected from among the plurality of second bonding pads is spaced apart from a second group of second bonding pads selected from among the plurality of second bonding pads based on a first imaginary line of symmetry passing through a center of the first semiconductor chip and a center of the plurality of second semiconductor chips and the first imaginary line of symmetry extending straight in the first horizontal direction, and
wherein the first group of second bonding pads are spaced apart from the second group of second bonding pads in a first horizontal direction with some of the plurality of first bonding pads therebetween.

10. The semiconductor package of claim 1, wherein a first group of second bonding pads selected from among the plurality of second bonding pads is spaced apart from a second group of second bonding pads selected from among the plurality of second bonding pads based on a second imaginary line of symmetry spaced apart from a center of the first semiconductor chip and a center of the plurality of second semiconductor chips and the second imaginary line of symmetry extending straight in the first horizontal direction, and
wherein the fixing parts of the first group of second bonding pads are to face each other with the fixing parts of the second group of second bonding pads.

11. A semiconductor package comprising:
a first semiconductor chip;
a plurality of second semiconductor chips sequentially stacked on the first semiconductor chip;
a plurality of conductive front pads on lower surfaces of the plurality of second semiconductor chips;
a plurality of conductive rear pads attached to an upper surface of the first semiconductor chip and an upper surface of each of the plurality of second semiconductor chips, from a planar perspective, and including a plurality of first bonding pads in central regions of the first semiconductor chip and the plurality of second semiconductor chips from a planar perspective and a plurality of second bonding pads in edge regions of the first semiconductor chip and the plurality of second semiconductor chips from a planar perspective; and
a plurality of chip connection terminals between the plurality of conductive front pads and the plurality of conductive rear pads, and
wherein each of the plurality of second bonding pads includes,
a supporting part configured to support each of the plurality of chip connection terminals; and
a fixing part protruding from the upper surface of the supporting part on one side of the supporting part.

12. The semiconductor package of claim 11, wherein upper surfaces of the plurality of first bonding pads are at a vertical level lower than upper surfaces of the fixing parts of the plurality of second bonding pads.

13. The semiconductor package of claim 11, wherein upper surfaces of the plurality of first bonding pads are at a same vertical level as upper surfaces of the supporting parts of the plurality of second bonding pads.

14. The semiconductor package of claim 11, wherein the fixing part and the supporting part vertically overlap with each of the plurality of conductive front pads.

15. The semiconductor package of claim 11, wherein the supporting part vertically overlaps with each of the plurality of conductive front pads, and wherein the fixing part does not vertically overlap each of the plurality of conductive front pads.

16. The semiconductor package of claim 11,
wherein a first group of second bonding pads selected from among the plurality of second bonding pads and on one side of the central regions are symmetrically arranged to face each other with a second group of second bonding pads selected from among the plurality of second bonding pads on an other side of the central regions.

17. The semiconductor package of claim 11,
wherein the first semiconductor chip and each of the plurality of second semiconductor chips comprise center regions having four sides and edge regions around the center region,
wherein the plurality of second bonding pads are in the edge regions and comprise first to fourth groups of second bonding pads around each of the four sides, and
wherein the fixing parts of each of the first to fourth groups of second bonding pads of are to face adjacent sides among the four sides.

18. A semiconductor package comprising:
a buffer chip;
a plurality of memory cell chips sequentially stacked on the buffer chip;
a plurality of first conductive front pads on a lower surface of the buffer chip;
a plurality of second conductive front pads on lower surfaces of the plurality of memory cell chips;
a plurality of conductive rear pads attached to an upper surface of the buffer chip and an upper surface of each of the plurality of memory cell chips, and from a planar perspective, including a plurality of first bonding pads in a central region of the buffer chip and the plurality of memory cell chips, and a plurality of second bonding pads in an edge region around the central region;
a plurality of package connection terminals respectively attached to the plurality of first conductive front pads;
a plurality of chip connection terminals between the plurality of second conductive front pads and the plurality of conductive rear pads;
a plurality of insulating adhesive layers between the buffer chip and each of the plurality of memory cell chips and surrounding a plurality of chip connection terminals; and
a molding layer surrounding the buffer chip, the plurality of memory cell chips, and the plurality of insulating adhesive layers, and
wherein each of the plurality of second bonding pads includes,
a supporting part configured to support each of the plurality of chip connection terminals; and
a fixing part protruding from the upper surface of the supporting part on one side of the supporting part and extending in a first horizontal direction;
wherein a first group of second bonding pads selected from among the plurality of second bonding pads are spaced apart from a second group of second bonding pads selected from among the plurality of second bonding pads based on a first imaginary line of symmetry passing through a center of the buffer chip and a center of the plurality of memory cell chips, and the first imaginary line of symmetry extending straight in the first horizontal direction, and
wherein the fixing parts of the first group of second bonding pads are to face each other with the fixing parts of the second group of second bonding pads.

19. The semiconductor package of claim 18, wherein, from a planar perspective, centers of the plurality of second bonding pads are within the supporting part, and
wherein a portion of an upper surface of the supporting part not covered by the fixing part has a larger area than an upper surface of the fixing part.

20. The semiconductor package of claim 18, wherein, from a planar perspective, the plurality of second bonding pads have an octagonal planar shape,
wherein the fixing part has a first sidewall facing a center of the plurality of second bonding pads and a second sidewall opposite to the first sidewall, and
wherein the first sidewall and the second sidewall are parallel to each other.
